(19) United States
(12) Patent Application Publication
(10) Pub. No.: US 2023/0421077 A1
(43) Pub. Date: Dec. 28, 2023

(54) System for Converting Vibrations, in Particular Sound Vibrations into Usable Electric Energy

(71) Applicant: Cuboid B.V., Ede (NL)

(72) Inventor: Vincent Daniël Van Hanxleden Houwert, Ede (NL)

(21) Appl. No.: 18/036,261

(22) PCT Filed: Nov. 10, 2021
(86) PCT No.: PCT/NL2021/050691

§ 371 Date: May 10, 2023

(30) Foreign Application Priority Data
Nov. 12, 2020 (NL) 2026885

(51) Int. Cl. H02N 2/18; B81B 3/00; H04R 3/00

(52) U.S. Cl. CPC H02N 2/188; B81B 3/0021; H04R 19/005; B81B 2207/053; H04R 3/00

(57) ABSTRACT

The present invention is related to a harvesting module for converting vibrations, in particular sound vibrations, into electric energy, comprising a substrate, having a surface for holding electronic components a plurality of parallel and/or serially connected transducers placed on the surface of the substrate, for receiving vibrations, in particular sound vibrations, and converting said vibrations into electric energy, a cover unit, positioned at least partially over the transducers, configured for passing on/transmit-ting/catching sound waves to the transducers, and blocking contaminants from the environment, such as dust or moisture, electric connector, for delivering the converted electric energy. The invention is further related to a harvesting device comprising said modules.

The present invention is related to harvesting modules for converting vibrations, in particular sound vibrations into usable electric energy, the invention is further related to a harvesting device using said modules.

Devices for converting sound into electric energy are known in the art. These devices however are not suitable for providing a continuous flow of energy such that they can be reliably utilized. The devices according to the prior art are furthermore not applicable in areas where significant power flows are to be retrieved in order to power a part of a device.

It is therefore a goal of the present invention to provide a device for delivering a more continuous flow of energy, wherein the energy is converted from vibrations into electric energy, or at least provide an alternative to the state of the art.

The present invention thereto proposes a harvesting module for converting vibrations, in particular sound vibrations, into electric energy, comprising; a substrate, having a surface for holding electronic components a plurality of parallel and/or serially connected transducers placed on the surface of the substrate, for receiving vibrations, in particular sound vibrations, and converting said vibrations into electric energy, and an electric connector, for delivering the converted electric energy. Preferably the harvesting module comprises a cover unit, positioned at least partially over the transducers, configured for transmitting sound waves to the transducers, and blocking contaminants from the environment, such as dust or moisture

The modules allow for a significant power flow for providing devices, or parts of devices with power. For example, if the modules are used inside a car to convert the sound vibrations into electrical vibrations, the harvested electric energy might be used to provide the low voltage system of the car with energy, as such the regular battery in the car that powers the low voltage system can be dimensioned smaller. The module could power interior lighting, or dashboard lighting, or the like. By connecting transducers serially the total voltage output can be increased, whereas by parallelly connecting transducers the amperage can be increased. Therefore, by selectively configuring the connections between the transducers, a usable power output can be obtained. In particular one or more strings of serially connected transducers could be parallelly mutually connected. Doing so the amount of power output can be designed according to the requirement of the application. The cover unit in the module fulfills more than one task. The primary task of the cover unit is to protect the transducers from contaminants, such as for example moisture or dirt. However, any other harmful contaminant that might damage the transducer is preferably blocked by the cover unit. Its secondary usage is that of a transmitter of the vibrations. Since the cover unit is positioned partly over the transducers, that is, such that the cover unit is able to protect against contaminants it could potentially isolate the transducer from the vibrations. Isolating the transducer from vibrations is to be avoided as much as possible in order to achieve the highest efficiency. The cover unit is therefore configured to pass on vibrations, whilst blocking contaminants. Moreover, the cover unit is able to substantially block pressure. This is especially beneficial in areas where there is a lot of surface wind or air pressure. The transducers could under such circumstances lock in a position by the constant flow of wind, and as a consequence stop converting energy. The cover unit thus encapsulates the transducers with a minimum loss of sound vibration energy.

In a different embodiment of the present invention the substrate is a printed circuit board, and wherein the cover unit is mounted on the printed circuit board. By using a printed circuit board, components can be easily mutually connected. The parallel and serially connections can also be formed on the printed circuit boards in a different embodiment. In order to prevent that transducers have to be individually placed on the printed circuit board, a micro-electromechanical system (MEMS) can be used. In particular MEMS transducers can be formed. MEMS systems is a process technology that is used to create small integrated devices or systems that combine mechanical and electrical component. A MEMS-package can be designed, which could be connected to the printed circuit board easily. The cover unit can also be mounted to the printed circuit board easily, this ensures a correct placement over preferably all transducers.

In a further embodiment according to the present invention the cover unit is mounted on the printed circuit board on flexible mounts. Mounting the cover unit on flexible mounts yields a higher efficiency of electric power that is harvested. This is a direct result of the flexible mounting. When using a rigid mounting of the cover unit, the cover unit is solidly attached to the printed circuit board and hence is only able to move by elastically deforming a portion of the cover unit itself. Whereas on the other hand when flexible mounts are used, the entire cover unit is allowed to move. This movement can be in a direction from and towards the printed circuit board, but can also be parallel to the printed circuit board. Either way, the movement allows more sound vibrations to pass through the cover unit without being damped too much. The flexible mounts may for example be formed out of silicone, connecting the cover unit to the printed circuit board. It is also conceivable that the cover unit is connected to a layer of flexible material, which flexible material forms the flexible mounts. That is, the transducers are surrounded by the flexible material, to which the cover unit is connected.

In yet another embodiment of the present invention the printed circuit board is in particular a double sided printed board, wherein the transducers are placed on both sides of the circuit board, and wherein the cover unit is positioned at least partially over the transducers on both sides. The cover unit can either be enclosing the entire module, such that the transducers on both sides of the printed circuit board are protected from contaminants, and can receive sound vibrations. But it is also conceivable that the module is provided with a second cover unit, wherein either side of the printed circuit board is provided with a single cover unit. By applying transducers on both sides of the printed circuit board, a higher amount of transducers per surface area of the module is achieved, which is desirable for obtaining a usable amount of power. Besides using a double-sided printed circuit board, one can also use two identical printed circuit boards, wherein one of the surfaces is provided with transducers, and wherein the other, essentially empty, side of the printed circuit boards are mounted to each other.

In a different embodiment the module comprises a housing, said housing substantially enclosing the entire module, wherein the module is at least partially flexible moving. In some circumstances, for example in somewhat rough conditions, more protection against elements is needed. Such protections can be achieved by enclosing the module with a housing. Said housing can be formed out of any material, as long as the vibrations are transmitted to the transducers. These rough conditions might for example occur in waterfalls, where the noise vibrations of the waterfall, or the like, can be converted into electric energy. To this end the housing should be entirely waterproof such that none of the components break down by the sheer force of the water. Depending on the type of transducers that is used, it could be beneficial to somewhat damp the vibrations by the housing, such that the transducers are not overloaded and are provided with the amount of vibrations that they can continuously transfer into electrical energy.

In yet a different embodiment according to the present invention the cover unit is connected directly to the plurality of transducers, such that the transducers are moved simultaneously by the cover unit. By connecting the cover unit to the plurality of transducers the energy converted will be of a more constant flow, since mutual differences in the output of the transducers are eliminated. It is furthermore beneficial since the cover unit can in general be configured for receiving the sound vibrations. When the cover unit receives said vibrations, it can pass on the vibrations to all transducers simultaneously. As such, even when only a part of the cover unit receives vibrations, all transducers are still moved regardless of which portion of the cover unit received the vibrations. Therefore, the module according to this embodiment is able to significantly increase the yield of harvested electric energy. When the vibrations will only be received by a small number of transducers, said cover unit can thus ensure that still all transducers are moved simultaneously, which will evidently yield more electric energy than the case that only a small number is moved. It should be understood that the cover unit can in general also be connected to a group of transducers, said group being formed out of a number of the plurality of transducers. A plurality of cover units can be installed, each connected directly to a group of transducers formed out of the plurality of transducers. Especially when opting to apply a housing on the outside of the module, this construction might be beneficial for the harvested electric energy. Since the housing is formed out of a flexible material, large areas of said housing can resonate and/or vibrate, passing on the resonance and/or vibrations to the cover unit which on its turn passes the resonance and/or vibrations on to all transducers simultaneously.

In again a different embodiment the cover unit is a flexible silicone and/or epoxy gel, wherein the transducers are enclosed by the silicone and/or epoxy gel. The silicone and/or epoxy gel in particular works well, since the sound vibrations are transmitted by the housing towards all transducers in an equally distributed manner by the silicone and/or epoxy gel. However, the silicone and/or epoxy gel also has benefits on its own. For example, the silicone and/or epoxy gel work very well to prevent contaminants from damaging the module. Moreover, it will not break in case of strong bending, which can be used to its advantage in combination with flexible printed circuit boards. The combination of flexible printed circuit boards, and the silicone and/or epoxy gel allows to manufacture a flexible module. Such a flexible module could be installed on any surface due to the flexibility. This way, shapes where aerodynamics play an important role can still be equipped with a harvester according to the invention without significantly disturbing the aerodynamics. The silicone and/or epoxy gel could be formed as a sheet which houses the transducers, wherein the transducers can still receive the vibrations of the sound to generate electric energy. Hence, the silicone and/or epoxy gel could be used in two separate ways. First as a transportation mechanism for transmitting sound vibrations from a casing to all transducers simultaneously, and secondly as a protective layer around all transducers, wherein the electronic components and connections are protected by the layer, but wherein the transducers are exposed such as to receive sound vibrations. Both ways could be combined with the flexible printed circuit board, such that the application can be used in areas where aerodynamics are important.

In yet again a different embodiment the cover unit is formed by a layer of silicone and/or epoxy material, together with a plastic or foamed layer. The silicone is placed such that it surrounds the transducers, and the plastic or foamed layer is adhered to said silicone.

In again a different embodiment the cover unit is formed by a foamed material, wherein the cavities in the foamed material are configured for receiving and transmitting multiple sound waves to the transducers. The foamed material, such as a foamed aluminum may comprise many differently sized cavities. The material should preferably be a non-absorbing material. Using such a material as much of the vibrations as possible will reach the transducers. The cavities are suitable for catching the vibrations of many different vibration frequencies since each cavity receives a unique frequency or unique range of frequencies. This embodiment is in particular beneficial for use inside speakers. Speakers generally emit sound to a room. However, inside the speaker cabinet sound vibrations also travel towards the panels of the cabinet, where they might lead to undesirable resonance of the cabinet. If a module comprising such a foamed material is positioned on one or more panels, for absorbing the sound vibrations emitted inside the cabinet, valuable energy can be converted to potentially power a part of the speaker.

In an alternative embodiment the harvesting module is configured for loud areas, wherein a sound level is above 75 dB, preferably above 85 dB, more preferably above 95 dB. Particularly in loud areas there is a lot of potential energy to be harvested. It has turned out that the present invention is able to, in such areas, deliver significant amounts of electric energy. This energy can be used for powering small appliances on the area.

In again an alternative embodiment a plurality of diodes and capacitors are used to stabilize the converted electric energy flow into a usable electric energy flow. Transducers have the tendency to produce a oscillating output. This oscillation is undesirable in usable power, therefore the output from the plurality of transducers has to converted into a usable power. To this end diodes and capacitors stabilize and/or harmonize the power output of the plurality of transducers such that a usable power output is gained. Usable in this application means, without substantial fluctuations such that regular appliances can be directly connected to the power output, without breaking the appliances.

In a different embodiment of the harvesting module the transducers are in particular electret transducers. It has turned out that this type of transducer is in particular suitable for collecting the sound vibrations and converting them into electric energy.

In a different embodiment the module comprises at least 600 transducers, preferably at least 1000 transducers, more preferably at least 1400 transducers. This number of transducers has turned out to deliver a constant and usable flow of electric power. The transducers may be connected serially and parallelly as the appliance it delivers power to requires. For instance, sometimes a high current might be necessary, and other times high voltage might be required. Whatever connection between the transducers is chosen, the amount turned out to provide enough flexibility to adapt according to the requirements of the appliances, and still provide usable electric power. The transducers might furthermore be divided over multiple harvesting fields, that is, smaller groups of transducers, wherein the harvesting fields can also mutually be connected parallelly or serially. However, lower numbers of transducers could be possible in case of highly efficient transducers which are capable of recovering more electric energy out of the vibrations, and can withstand higher sound levels for longer.

Preferably the module comprises at least one switching array, wherein at least two, preferably all transducers are electrically connected to said switching array, wherein the switching array is configured for selectively parallelly and/or serially connecting a number of transducers. It is moreover conceivable that at least one controller is configured for controlling the switching array based on a predetermined control signal. This particular embodiment is beneficial given that the module may be applied in a wider range of environments without additional burden on installation and/or design. By selectively selecting the amount of transducers to be connected in series and parallel, the module may easily adapt, without a redesign of the substrate, to a new environment. To this end it is preferred that the controller and/or the switching array is configured to maintain the level of resistance below a threshold value. Preferably, the controller and/or switching array is configured to keep the current below a level to which the cables are rated, and if more energy is produced by the transducers, the amount of parallelly connected transducers may be reduced and the amount of serially connected transducers increased, such that the produced current remains within the spec of the cables.

Preferably, the switching array is configured to select, based on a sound level and/or pressure level, the amount of transducers connected serially and/or the amount of transducers connected parallelly. Wherein preferably the harvesting module further comprising a pressure measurement component, for determining a sound level and/or a pressure level. As such, the controller and/or switching array may switch fully autonomously, based on said control value such as the sound pressure, and optionally the threshold value to which the components of the module are rated, the amount of serially and/or parallelly connected transducers. If for example suddenly there is an increase of sound level, the pressure measuring component will detect this increase, based upon the increase of sound level the controller and/or switching array may determine to reduce the amount of parallelly connected transducers, and increase the amount of serial connections, such that the current remains within an acceptable range, preventing damage to the components. Moreover, it is conceivable to use said pressure measuring component to detect a current sound level and/or pressure level, additionally, a requirement set to the device in terms of output signal may be provided to the controller and/or switching array, based on which the switching array and/or controller may determine the optimum settings to provide a usable electric energy.

The switching array preferably comprises a plurality of N×M switches, each for electrically connecting a unique combination of an input connection with an output connection, wherein the switching array and/or controller is configured for controlling the N×M switches. The input and output connections may be connections to a specific transducer. The harvesting module according to the invention, in particular the switching array may be configured for switching either an AC signal, or a DC signal. Whether an AC or DC switching array is used may be determined based on the electrical location of said array. In case the array is situated before a rectifier setup the array may be configured to switch AC signals, whereas in case the switching array is located after the rectifier, it may be configured for switching DC signals.

The present invention is also related to a harvesting device for converting vibrations, in particular sound vibrations, into electric energy, comprising, a module holder frame, said holder frame comprising a plurality of module connectors, each module connector configured to receive an electric connector of the harvesting module according to the present invention, electrical connections, for mutually serially and/or parallelly mutually electrically connecting the plurality of harvesting modules connected to the module connectors, a power connector, configured for receiving, from the electrical connections, electric energy from the one or more connected harvesting modules, delivering the accumulated electric energy of the one or more harvesting modules. The harvesting device according to the invention has the same benefits as the harvesting module, and the mentioned benefits are hereby incorporated. The harvesting device is furthermore beneficial for modular use of the harvesting modules. The harvesting modules are configured to be connected to the harvesting device, increasing the potential electric energy yield. It is also convenient when a module or a component of a module breaks down, it is not required to shut down the entire device, just the single module that is defective, or has an internal defect in one of its components, has to be replaced. In the meanwhile, energy can still be converted during replacement of the broken module.

In a different embodiment the harvesting field comprises at least 10 harvesting modules, preferably 15 modules, more preferably at least 25 modules. It has turned out that using this amount of modules, the size of the device is exactly right. The device can still be handled, transported and repaired without requiring different or complex tools. The number of modules however can be amended according to the desired application, and should therefore not be interpreted limitative.

In yet a different embodiment of the harvesting device the device further comprises one or more energy storage cells, such as batteries, for temporarily storing the accumulated electric energy of the one or more harvesting modules. Storing energy in a storage cell such as a battery might be required since not all appliances continuously require electric power. It would be a waste of harvested electric energy if it is not stored or used. Therefore, in case there is no load connected to the device that requires an electric power, and there is noise available for converting more energy, energy storage cells provide a location to temporarily store energy. Also, in case there is a shortage of noise to be converted into electric energy, and the connected appliance still requires electric power, the storage cells provide a usable outcome.

In a different embodiment the harvesting device is integrated into or onto a product, such as a speaker, windmill, transport device or the like, for powering at least a portion of the product. This allows for efficient use of the energy on the location. Some locations are in a substantially continuously noisy area, which is very much suitable for continuous generation of electric energy to power at least a portion of the product.

Preferred embodiments of the present invention are set out in the following non-limitative clauses.

### CLAUSES

1. Harvesting module for converting vibrations, in particular sound vibrations, into electric energy, comprising;
   a substrate, having a surface for holding electronic components;
   a plurality of parallel and/or serially connected transducers placed on the surface of the substrate, for receiving vibrations, in particular sound vibrations, and converting said vibrations into electric energy,
   an cover unit, positioned at least partially over the transducers, configured for transmitting sound waves to the transducers, and blocking contaminants from the environment, such as dust or moisture,
   an electric connector, for delivering the converted electric energy.
2. Harvesting module according to clause 1, wherein the substrate is a printed circuit board, and wherein the cover unit is mounted on the printed circuit board.
3. Harvesting module according to clause 2, wherein the cover unit is mounted on the printed circuit board on flexible mounts.
4. Harvesting module according to any of clauses 2-3, wherein the printed circuit board is in particular a double sided printed board, wherein the transducers are placed on both sides of the circuit board, and wherein the cover unit is positioned at least partially over the transducers on both sides.
5. Harvesting module according to clause 4, wherein the module comprises a housing, said housing substantially enclosing the entire module, wherein the module is at least partially flexible moving.
6. Harvesting module according to any of the preceding clauses, wherein the cover unit is connected directly to the plurality of transducers, such that the transducers are moved simultaneously by the cover unit.
7. Harvesting module according to any of the preceding clauses, wherein the cover unit is a flexible silicone and/or epoxy gel, wherein the transducers are enclosed by the silicone and/or epoxy gel
8. Harvesting module according to any of the preceding clauses, wherein the cover unit is formed by a foamed material, wherein the cavities in the foamed material are configured for receiving and transmitting multiple sound waves to the transducers.
9. Harvesting module according to any of the preceding clauses, wherein the harvesting module is configured for loud areas, wherein a sound level is above 65 dB, preferably above 80 dB, more preferably above 95 dB.
10. Harvesting module according to any of the preceding clauses, wherein a plurality of diodes and capacitors are used to stabilize the converted electric energy flow into a usable electric energy flow.
11. Harvesting module according to any of the preceding clauses, wherein the transducers are in particular electret transducers.
12. Harvesting module according to any of the preceding clauses, wherein the module comprises at least 600 transducers, preferably at least 1000 transducers, more preferably at least 1400 transducers.
13. Harvesting device for converting vibrations, in particular sound vibrations, into electric energy, comprising,
   a module holder frame, said holder frame comprising;
      a plurality of module connectors, each module connector configured to receive an electric connector of the harvesting module according to any of the clauses 1-12,
electrical connections, for mutually serially and/or parallelly mutually electrically connecting the plurality of harvesting modules connected to the module connectors,
a power connector, configured for;
   receiving, from the electrical connections, electric energy from the one or more connected harvesting modules,
   delivering the accumulated electric energy of the one or more harvesting modules.
14. Harvesting device according to clause 13, wherein the harvesting field comprises at least 10 harvesting modules, preferably 15 modules, more preferably at least 25 modules.
15. Harvesting device according to any of the clauses 13-14, wherein the device further comprises;
   one or more energy storage cells, such as batteries, for temporarily storing the accumulated electric energy of the one or more harvesting modules
16. Harvesting device according to any of the clauses 15, wherein the harvesting field is integrated into or onto a product, such as a speaker, windmill, transport device or the like, for powering at least a portion of the product.

The present invention will hereinafter be further elucidated based on the following drawings, wherein:

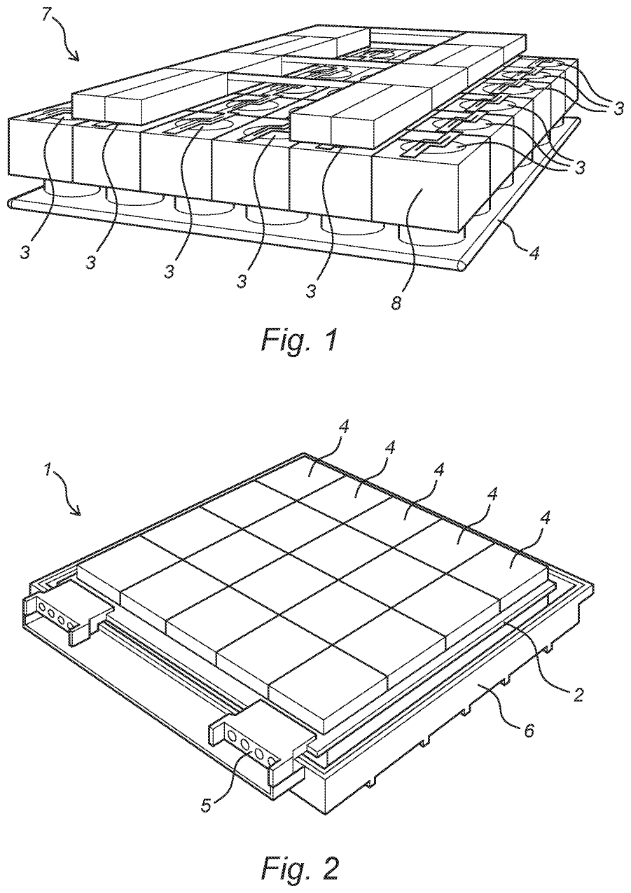

FIG. 1 shows a perspective view of a segment of transducers of a harvesting module according to an embodiment;

FIG. 2 shows a laid open view of a harvesting module according to the present invention;

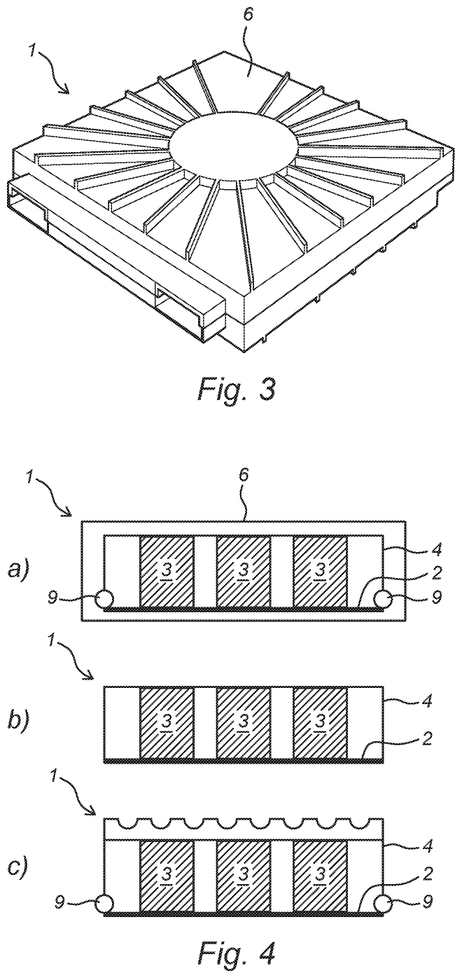

FIG. 3 shows a closed view of the harvesting module shown in FIG. 2, and

FIG. 4 a-c shows schematic representations of various embodiments of the harvesting module.

FIG. 1 shows a perspective view of a segment 7 of transducers 3. The harvesting module 1 may comprise a plurality of such segments 7. The segment 7 in this particular embodiment comprises 3 times 12 transducers 3, mutually parallelly and serially connected. Each transducer 3 is housed inside a compression chamber 8, which is about 25 square millimeters. The transducers 3 are able to resonate inside the compression chamber 8. On the bottom side, the transducers are placed on a silicone cover unit 4, which serves to protect the transducers 3 but also to simultaneously activate all transducers 3 at the same time.

FIG. 2 shows a perspective view of a different harvesting module 1. The harvesting module 1 may comprise a plurality of segments 7 as shown in FIG. 1. In this particular embodiment the segments 7 are placed inside a cover unit 4, which seals substantially the entire exposed surface of the segments 7. All of the segments 7 are connected to a printed circuit board 2, which serves as the substrate 2. In this embodiment the printed circuit board 2 is in particular double sided. That is, also the bottom surface of the printed circuit board 2 comprises a plurality of the segments 7. This increases the amount of transducers 3 per square meter, and hence the potential energy to be harvested. The module 1 further shows an electric connector 5, for delivering the converted electric energy. Or, in case a plurality of modules are used, for coupling with a connector. All components are housed inside a housing 6, which protects the components. This in particular would be a module 1 suitable for harsh environments, since the housing 6 makes a water tight seal around the components, as such the module 1 can be used for example inside a waterfall, or other location that desires a high degree of water tightness. FIG. 3 shows the module 1 according to the present invention as a whole, wherein also the top half of the housing 6 is assembled. The central part of the top surface of the housing 6 is in particular rigid. The top surface is configured to move by means of resonance of the sound vibrations, or by means of a high volume stream of water over the surface. The surfaces passes the vibrations to the transducers placed inside and is able to generate an electric energy.

Lastly, FIG. 4a-4c show schematic illustrations of embodiments of the module 1. FIG. 4a shows a schematic perspective of the module 1 wherein transducers 3 (for illustrative purposes only 3) are placed on the substrate 2, which is in particular a printed circuit board 2. The cover unit 4 is placed on the substrate 2 by means of flexible mounts 9. Flexible mounts 9 could be formed out of any flexible material, such as silicone. The cover unit 4 is directly positioned over the top surfaces of the transducers 3, such that it can transmit as many waves in a constant frequency as possible to the transducers 3. Enclosing everything is a rigid housing 6, which protects the interior system against the environment. This makes this embodiment in particular suitable for use in for example transportation such as cars, trucks, trains, subways, busses and the like. To this end, the housing 6 can be either flexible in order to pass on the sound waves to the transducers or rigid if the sound is too loud for the transducers 3.

In another embodiment, displayed in FIG. 4b, the cover unit 4 is placed directly on the printed circuit board 2, without the flexible mounts 9. The transducers 3 are individually able to capture vibrations from the sound waves.

The embodiments shown in FIGS. 4a and 4b can be made in an electronic component for easy placement on large scale. This can for example be realized by means of a micro-electromechanical system (MEMS), however a micro-PCB can also be used to this end.

The last embodiment shows an cover unit 4 formed out of a foamed material, such as foamed aluminum. Which is mounted to the printed circuit board 2 by means of flexible mounts 9. The foamed material 4 is positioned directly onto the transducers and captures as many frequency waves as possible. This embodiment is in particular suitable for installation on a panel inside a speaker cabinet, since it can receive various frequencies efficiently.

1. Harvesting module for converting vibrations, in particular sound vibrations, into electric energy, comprising;
a substrate, having a surface for holding electronic components;
a plurality of parallel and/or serially connected transducers placed on the surface of the substrate, for receiving vibrations, in particular sound vibrations, and converting said vibrations into electric energy,
an electric connector, for delivering the converted electric energy.

2. Harvesting module according to claim 1, comprising a cover unit, positioned at least partially over the transducers, configured for transmitting sound waves to the transducers, and blocking contaminants from the environment, such as dust or moisture.

3. Harvesting module according to claim 2, wherein the substrate is a printed circuit board, and wherein the cover unit is mounted on the printed circuit board.

4. Harvesting module according to claim 2, wherein the cover unit is mounted on the printed circuit board on flexible mounts.

5. Harvesting module according to claim 1, wherein the printed circuit board is in particular a double sided printed board, wherein the transducers are placed on both sides of the circuit board, and wherein the cover unit is positioned at least partially over the transducers on both sides.

6. Harvesting module according to claim 5, wherein the module comprises a housing, said housing substantially enclosing the entire module, wherein the module is at least partially flexible moving.

7. Harvesting module according to claim 1, wherein the cover unit is connected directly to the plurality of transducers, such that the transducers are moved simultaneously by the cover unit.

8. Harvesting module according to claim 1, wherein the cover unit is a flexible silicone and/or epoxy gel, wherein the transducers are enclosed by the silicone and/or epoxy gel

9. Harvesting module according to claim 1, wherein the cover unit is formed by a foamed material, wherein the cavities in the foamed material are configured for receiving and transmitting multiple sound waves to the transducers.

10. Harvesting module according to claim 1, wherein the harvesting module is configured for loud areas, wherein a sound level is above 65 dB, preferably above 80 dB, more preferably above 95 dB.

11. Harvesting module according to claim 1, wherein a plurality of diodes and capacitors are used to stabilize the converted electric energy flow into a usable electric energy flow.

12. Harvesting module according to claim 1, wherein the transducers are in particular electret transducers.

13. Harvesting module according to claim 1, wherein the module comprises at least 600 transducers, preferably at least 1000 transducers, more preferably at least 1400 transducers.

14. Harvesting module according to claim 1, wherein the module comprises at least one switching array, wherein at least two, preferably all transducers are electrically connected to said switching array, wherein the switching array is configured for selectively parallelly and/or serially connecting a number of transducers.

15. Harvesting module according to claim 14, wherein the switching array is configured to select, based on a sound level and/or pressure level, the amount of transducers connected serially and/or the amount of transducers connected parallelly.

16. Harvesting module according to claim 14, wherein the harvesting module further comprising a pressure measurement component, for determining a sound level and/or a pressure level.

17. Harvesting device for converting vibrations, in particular sound vibrations, into electric energy, comprising,
a module holder frame, said holder frame comprising;
a plurality of module connectors, each module connector configured to receive an electric connector of the harvesting module according to claim 1,
electrical connections, for mutually serially and/or parallelly mutually electrically connecting the plurality of harvesting modules connected to the module connectors,
a power connector, configured for;
receiving, from the electrical connections, electric energy from the one or more connected harvesting modules,
delivering the accumulated electric energy of the one or more harvesting modules.

18. Harvesting device according to claim 17, wherein the harvesting field comprises at least 10 harvesting modules, preferably 15 modules, more preferably at least 25 modules.

19. Harvesting device according to claim 17, wherein the device further comprises;
one or more energy storage cells, such as batteries, for temporarily storing the accumulated electric energy of the one or more harvesting modules.

20. Harvesting device according to claim 19, wherein the harvesting field is integrated into or onto a product, such as a speaker, windmill, transport device or the like, for powering at least a portion of the product.
